(19) United States
(12) Patent Application Publication
(10) Pub. No.: US 2018/0226353 A1
(43) Pub. Date: Aug. 9, 2018

(54) SEMICONDUCTOR LEAD FRAME WITH MACHINE READABLE MARK

(71) Applicant: NXP B.V., Eindhoven (NL)

(72) Inventors: Ekapong Tangpattanasaeree, Bangkok (TH); Wiwat Tanwongwan, Bangkok (TH); Amornthep Saiyajitara, Bangkok (TH)

(21) Appl. No.: 15/427,010

(22) Filed: Feb. 7, 2017

(51) Int. Cl. H01L 23/544; H01L 21/48; H01L 23/495

(52) U.S. Cl. CPC H01L 23/544; H01L 2223/54413; H01L 23/49541; H01L 21/4821

(57) ABSTRACT

A lead frame used in semiconductor device assembly includes first and second opposing planar surfaces. A marking area is defined on the first planar surface. The marking area has a uniform background color that is different from a color of the first planar surface. A mark is formed in the marking area. The background color of the marking area contrasts with a color of the mark such that a clear image of the mark is easily captured with an image sensor. The mark preferably is a two-dimensional (2D) mark made of bumps and represents encoded information. The contrast between the background color and the mark is especially helpful when the lead frame has a roughened surface.

### BACKGROUND

The present invention is related to product marking and, more particularly, to marking a lead frame used in semiconductor device assembly with a machine readable mark.

Conductive lead frames, usually formed from a copper strip or sheet, are used in semiconductor device assembly to provide input and output pins to a semiconductor die. Lead frames also can provide enhanced heat transfer to assist in dissipating heat generated by the integrated circuit within the die. The copper sheet may be treated or pre-treated with chemicals to enhance adhesion between an encapsulant material and the metal lead frame. The lead frame also may include a pre-plated finish (PPF) to prevent oxidation of the copper. The chemical treatment processes result in micro-roughening of the copper surfaces.

Lead frames, lead frame strips, and lead frame arrays are marked either when fabricated or during device assembly to associate certain information with the lead frame and/or the device being assembled. Such marking typically is done using a laser marking machine. FIG. 1A shows a semiconductor device assembly flow 10 for a lead frame/wire bond type device. In a first step 12, one or more lead frames on a lead frame strip or array are marked with information by creating a two-dimensional (2D) code on the lead frame. In a next step 14, a semiconductor die is attached to the lead frame. Leads of the lead frame are electrically connected to bonding pads of the die in a wire bonding step 16. After wire bonding, the sub-assembly is covered with a molding compound at step 18, and finally, at step 20, the assembled device is cleaned, such as by deflashing or removing excess molding compound.

FIG. 1B shows an example of a 2D-code 22 formed on a part of a lead frame 24. The code or marking 22, in this case, comprises a plurality of raised dots or bumps 26. FIG. 1C shows a lead frame 28 passing beneath a 2D-code reader or camera 30, which takes an image of the code 22 and processes the image using image recognition software to extract the encoded information.

Unfortunately, when marking the 2D-code 22 on a lead frame, a non-uniform color will appear in the marking area and the background surface, caused by the laser burning the metal. The problem is exacerbated when the surface of the lead frame is roughened, such as by the chemical processes discussed above. The non-uniform color can blur the contrast between the 2D-code and the background surface, making it difficult for the camera to obtain a good, readable image of the code, and misreading of the matrix code by the reader can cause unnecessary yield losses.

Accordingly, it would be advantageous to be able to create an enhanced or more readily readable mark on a lead frame.

### BRIEF DESCRIPTION OF THE DRAWINGS

The present invention is illustrated by way of example and is not limited by embodiments thereof shown in the accompanying figures, in which like references indicate similar elements. Elements in the figures are illustrated for simplicity and clarity and have not necessarily been drawn to scale.

FIG. 1A is a flow diagram of a conventional process for assembling a semiconductor device; FIG. 1B is a photograph of a conventional encoded mark formed on a lead frame; and FIG. 1C is a side view of a conventional image capture system capturing an image of a mark on a lead frame;

FIG. 2 is photograph of an encoded mark in accordance with an embodiment of the present invention;

FIG. 3 is a flow diagram of a method of assembling a semiconductor device including a mark on a lead frame thereof in accordance with an embodiment of the present invention;

FIG. 4 is a series of diagrams illustrating the creation of a mark on a lead frame in accordance with an embodiment of the present invention; and

FIG. 5 is a top plan view of an encoded mark in accordance with an embodiment of the present invention.

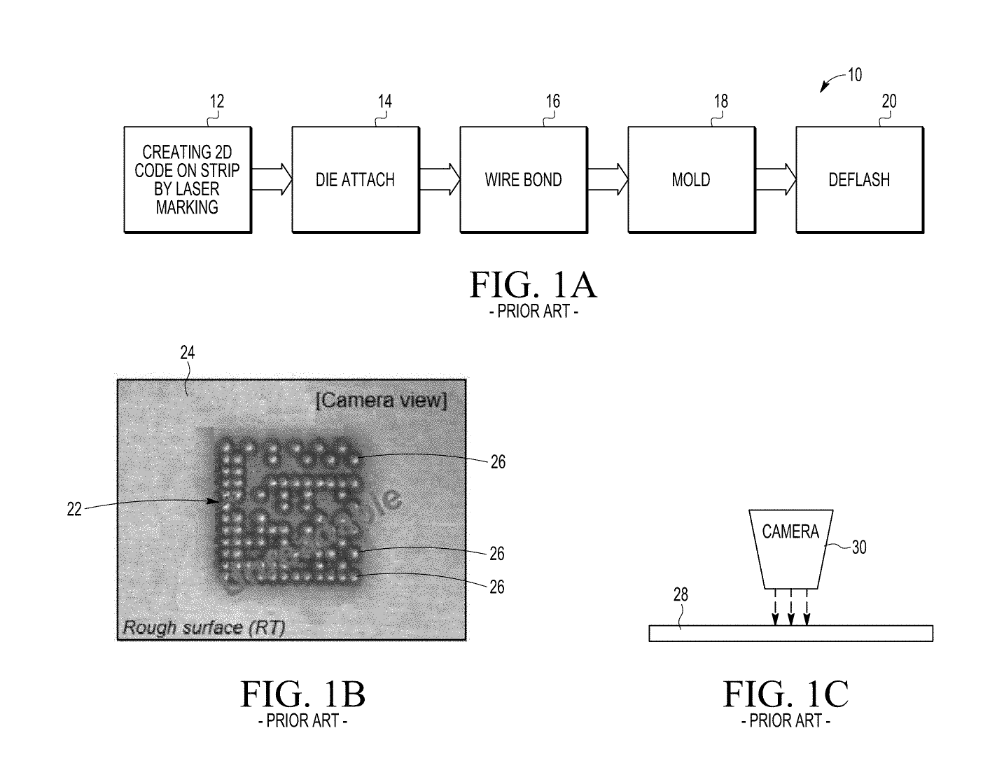

### DETAILED DESCRIPTION

The present invention provides a method of making a uniform color on a background surface of a roughened lead frame by laser marking to enhance the readability of a 2D mark formed over the colored background surface by a 2D code reader machine. For a lead frame with a smooth surface, there generally is a contrast between a 2D code and the background surface, allowing the 2D reader to read the 2D code accurately. However, for lead frames with a roughened surface, due to limitations of the image processing, the 2D code reader machine has difficulty interpreting a code formed over a non-uniform grayscale background.

In one embodiment, the present invention is a method of marking a planar surface of a lead frame used in semiconductor device assembly, including the steps of selecting an area of the lead frame for marking, creating a uniform background color in the marking area, and creating a mark within the marking area and on the background color, where the background color contrasts with a color of the mark such that a clear image of the mark is easily captured with an image sensor.

In another embodiment, the present invention is a lead frame used in semiconductor device assembly. The lead frame has first and second planar surfaces, where at least the first planar surfaces is roughened. A marking area having a first length L1 and a first width W1 is defined on the first planar surface. The marking area has a uniform background color that is different from a color of the first planar surface. There is a mark in the marking area, wherein the background color of the marking area contrasts with a color of the mark such that a clear image of the mark is easily captured with an image sensor.

As used herein, a smooth or normal lead frame surface has a surface roughness RT=0.05-0.07, while a rough surface has a roughness RT>1.2.

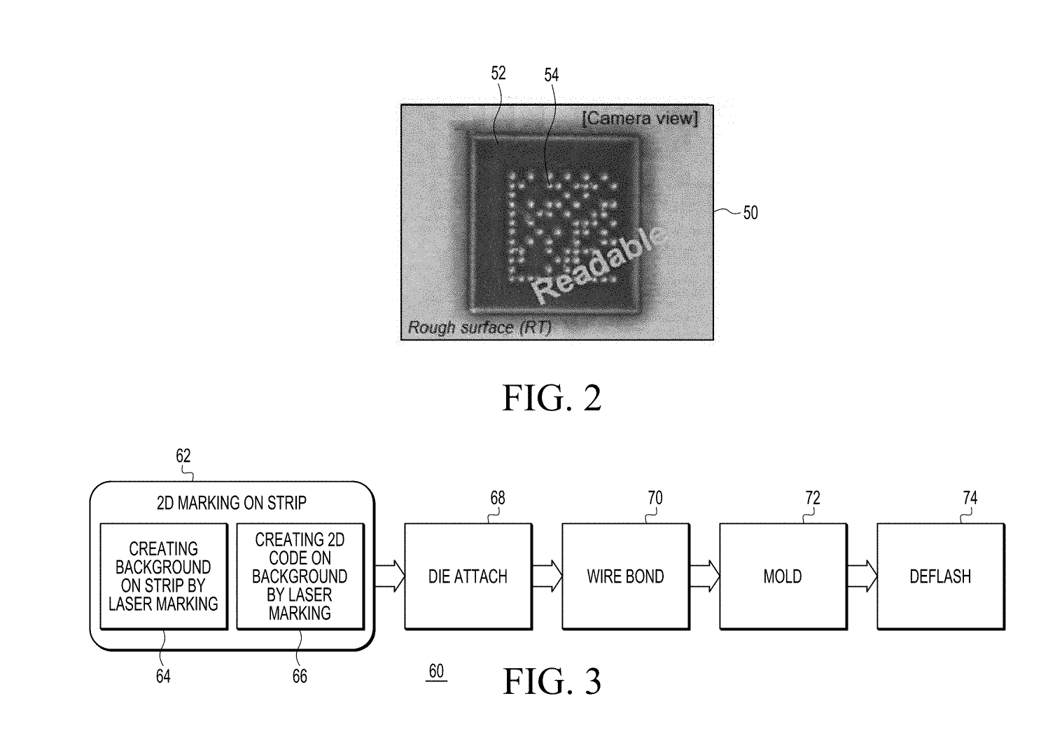

Referring now to FIG. 2, a photograph of a portion of a lead frame 50 having a roughened planar surface is shown. The lead frame 50 has a marking area 52 that has a uniform background color that is different from a color of the first planar surface. In one embodiment, the background color is black. A mark 54 is located in the marking area 52. The background color of the marking area 52 contrasts with a color of the mark 54 such that a clear image of the mark 54 can be easily captured by a camera or image sensor. In one embodiment, the mark 54 comprises a 2D encoded mark formed by a plurality of bumps and has a white color or at least a brightness that is greater than a brightness of the background color. The encoded mark 54 contains information about the lead frame and device being assembled using the lead frame.

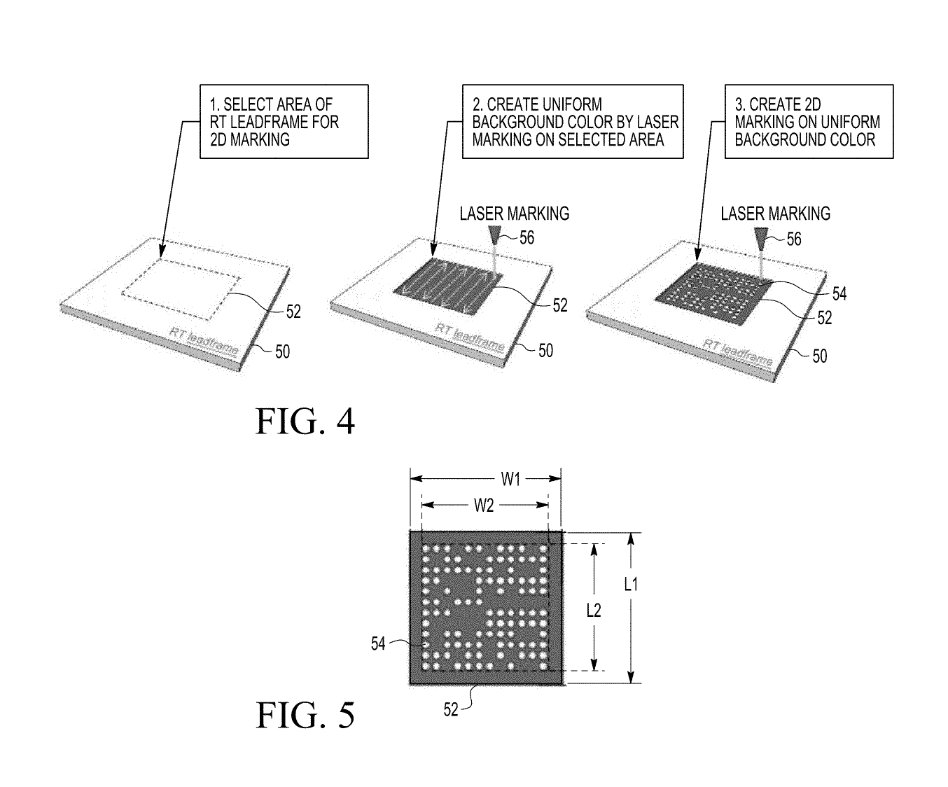

FIG. 3 is a flow diagram 60 of a method of assembling a semiconductor device including a mark on a lead frame thereof in accordance with an embodiment of the present invention, and FIG. 4 is a series of diagrams illustrating the creation of a mark on a lead frame in accordance with an embodiment of the present invention.

In the flow diagram 60, the method is for assembling a lead frame based semiconductor device, which includes both flip-chip and wire bond devices. In a first step 62, a 2D mark is formed in a marking area of a lead frame strip using a laser marking machine. Step 62 will be described in conjunction with the diagrams shown in FIG. 4. In a first sub-step 64, an area 52 of the lead frame strip 50 is selected for marking, as shown in the first or leftmost diagram of FIG. 4. The selected area preferably is any area of the lead frame that will be visible after molding—that is, an area that will not be covered by molding compound. Next, the marking area 52 is shaded or colored, using a laser marking machine 56 so that the marking area 52 has a uniform background color, as shown in the middle diagram of FIG. 4. In the presently preferred embodiment, the background color is black and is formed using a laser beam of a marking machine at high power and low speed, where high power means more than about 8 W and low speed means less than about 250 mm/sec. In one embodiment, the laser beam is used to burn or sear the top surface of the marking area 52 so that the marking area is blackened or black.

In a next sub-step 66, a mark 54 is created using the laser marking machine 56, where the mark 54 is within the marking area 52 and over the background color. The mark 54 preferably comprises a two-dimensional (2D) encoded mark comprising a plurality of bumps. The background color of the marking area 52 contrasts with a color of the mark 54 such that a clear image of the mark is easily captured with an image sensor. That is, the 2D matrix code 54 can be read by an image sensor of a CCD camera and was accurately interpreted using image recognition software to identify the package information encoded by the mark 54 and stored in a database.

Referring now to FIG. 3, the remainder of the semiconductor device assembly process includes attaching a die to the lead frame at 68, connecting bond wires between leads of the lead frame and I/O pads of the die at 70, encapsulating the lead frame, die and bond wires with a molding compound at 72, and then removing excess molding compound in a deflash step 74. The remaining steps are well known to those of skill in the art.

FIG. 5 is a top plan view of the lead frame 50 including the marking area 52 and the 2D mark 54 in accordance with an embodiment of the present invention. The marking area 52 has a first length L1 and a first width W1, and the mark 54 has a second length L2 and a second width W2. In the presently preferred embodiment, L1>L2 and W1>W2. In one example, L1=1.0 mm, W1=1.0 mm, L2=0.80 mm, and W2=0.8 mm. The mark 54 also has a depth 5 μm.

The invention is applicable to all lead frames but particularly for lead frames with a roughened surface. The background color and the 2D mark may be formed using known laser marking equipment, such as diode, fiber, and green or UV lasers, which makes marks that are readable using image processing systems. Example image processing systems are Cognex Dataman 300 Series Barcode Readers available from Cognex Corporation of Natick, Mass., and Keyence SR1000 Code Reader available from Keyence Corporation of Osaka, Japan.

In the foregoing specification, the invention has been described with reference to specific examples of embodiments of the invention. It will, however, be evident that various modifications and changes may be made therein without departing from the broader spirit and scope of the invention as set forth in the appended claims.

In the claims, the words ‘comprising’, ‘including’, and ‘having’ do not exclude the presence of other elements or steps then those listed in a claim. The terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The fact that certain measures are recited in mutually different claims does not indicate that a combination of these measures cannot be used to advantage.

1. A method of marking a planar surface of a lead frame used in semiconductor device assembly, the method comprising the steps of:
selecting an area of the lead frame for marking;
creating a uniform background color in the marking area; and
creating a mark within the marking area and on the background color, wherein the background color contrasts with a color of the mark such that a clear image of the mark is easily captured with an image sensor.

2. The method of claim 1, wherein the background color is created using a laser.

3. The method of claim 2, wherein the mark is created using the laser.

4. The method of claim 3, wherein the mark comprises a two-dimensional (2D) encoded mark.

5. The method of claim 4, wherein the 2D mark comprises a plurality of bumps formed in the surface of the lead frame.

6. The method of claim 1, wherein the colored background has a first length L1 and a first width W1, and the mark has a second length L2 and a second width W2, wherein L1>L2 and W1>W2.

7. A lead frame including a mark formed in accordance with the method of claim 1.

8. A lead frame used in semiconductor device assembly, comprising:
first and second opposing planar surfaces;
a marking area having a first length L1 and a first width W1 is defined on the first planar surface, wherein the marking area has a uniform background color that is different from a color of the first planar surface; and
a mark formed in the marking area, wherein the background color of the marking area contrasts with a color of the mark such that a clear image of the mark is easily captured with an image sensor.

9. The lead frame of claim 8, wherein the mark has a second length L2 and a second width W2, and L2<L1 and W2<W1.

10. The lead frame of claim 8, wherein the mark comprises a two-dimensional (2D) encoded mark.

11. The lead frame of claim 10, wherein the 2D mark comprises a plurality of bumps formed in the first planar surface of the lead frame.

12. The lead frame of claim 10, wherein the first planar surface of the lead frame is roughened.

13. A method of marking a planar surface of a work piece, the method comprising the steps of:
selecting an area of a first planar surface of the work piece for marking;
creating a uniform background color in the selected marking area; and
creating a mark within the selected marking area and on the background color, wherein the background color of the marking area contrasts with a color of the mark such that a clear image of the mark is easily captured with an image sensor.

14. The method of claim 13, wherein the background color is created using a laser.

15. The method of claim 14, wherein the mark is created using the laser.

16. The method of claim 13, wherein the mark comprises a two-dimensional (2D) encoded mark.

17. The method of claim 16, wherein the 2D mark comprises a plurality of bumps.

18. The method of claim 17, wherein the colored background has a first length L1 and a first width W1, and the mark has a second length L2 and a second width W2, wherein L1>L2 and W1>W2.

19. The method of claim 17, wherein the work piece comprises a lead frame used in semiconductor device assembly and the first planar surface of the lead frame has a roughened surface.
